(19) United States
(12) Patent Application Publication
(10) Pub. No.: US 2023/0326942 A1
(43) Pub. Date: Oct. 12, 2023

(54) IMAGE SENSOR

(71) Applicant: VisEra Technologies Company Limited, Hsin-Chu City (TW)

(72) Inventors: Chun-Yuan WANG, Hsin-Chu City (TW); Zong-Ru TU, Hsin-Chu City (TW); Yu-Chi CHANG, Hsin-Chu City (TW); Han-Lin WU, Hsin-Chu City (TW); Hung-Jen TSAI, Hsin-Chu City (TW)

(21) Appl. No.: 17/716,079

(22) Filed: Apr. 8, 2022

(51) Int. Cl. H01L 27/146

(52) U.S. Cl. CPC H01L 27/14627; H01L 27/14621; H01L 27/14623; H01L 27/1463

(57) ABSTRACT

An image sensor includes a sensor unit, a sensing portion disposed within the sensor unit, and an isolation structure corresponding to the sensing portion. The isolation structure includes a first deep trench isolation (DTI) structure surrounding the sensor unit from top view, and a second deep trench isolation structure laterally enclosed by the first deep trench isolation structure. The second deep trench isolation structure is located close to a corner of the sensor unit defined by the first deep trench isolation structure. The second deep trench isolation structure is asymmetrical with respect to a horizontal middle line or a vertical middle line within the sensor unit.

### BACKGROUND

### Technical Field

The present disclosure relates to an image sensor, and it particularly relates to the isolation structure of the image sensor.

### Description of the Related Art

Image sensors, such as complementary metal oxide semiconductor (CMOS) image sensors (also known as CIS), are widely used in various image-capturing apparatuses such as digital still-image cameras, digital video cameras, and the like. The light-sensing portion of the image sensor may detect ambient color change, and signal electric charges may be generated depending on the amount of light received in the light-sensing portion. In addition, the signal electric charges generated in the light-sensing portion may be transmitted and amplified, whereby an image signal is obtained.

Based on industrial demand, pixel size has continuously been reduced. In order to maintain high levels of performance, a group of pixels (such as the Phase Difference Auto Focus (PDAF) pixels) can be integrated into a conventional sensor array. Light received by the group of pixels may converge through the color filter, to be collected at the corresponding sensing portions at the bottom, and the image focus for the apparatus is detected. However, an image sensor with a reduced pixel size may experience a slight offset in precision, which can significantly affect the overall performance of the device. Therefore, these and related issues need to be addressed through the design and manufacture of the image sensor.

### SUMMARY

In an embodiment, an image sensor includes a sensor unit, a sensing portion disposed within the sensor unit, and an isolation structure corresponding to the sensing portion. The isolation structure includes a first deep trench isolation (DTI) structure surrounding the sensor unit from top view, and a second deep trench isolation structure laterally enclosed by the first deep trench isolation structure. The second deep trench isolation structure is located close to a corner of the sensor unit defined by the first deep trench isolation structure. The second deep trench isolation structure is asymmetrical with respect to a horizontal middle line or a vertical middle line within the sensor unit.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A is a cross-sectional view of an image sensor, according to some embodiments of the present disclosure.

FIG. 1B is a top view of the image sensor, according to some embodiments of the present disclosure.

FIGS. 2, 3, 4, 5, 6, and 7 are top views of the image sensor with various designs, according to some embodiments of the present disclosure.

FIGS. 8A-8F are top views of an image sensor with various designs, according to other embodiments of the present disclosure.

FIGS. 9, 10, 11, 12, 13, 14, 15, and 16 are top views of an image sensor with various designs, according to yet other embodiments of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean±20% of the stated value, more typically ±10% of the stated value, more typically ±5% of the stated value, more typically ±3% of the stated value, more typically ±2% of the stated value, more typically ±1% of the stated value and even more typically ±0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the prior art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In response to the continually reduced pixel size, light reception of each pixel, and light reception uniformity between pixels have become a critical concern. One method of enhancing light reception of smaller pixels among the image sensor is to integrate a group of sensor units (such as Phase Difference Auto Focus (PDAF) pixels). According to some embodiments of the present disclosure, when light is evenly received by each sensor unit within the group, the image sensor can display image of unifying color. However, if light received by each sensor unit is uneven, then the image sensor would experience color variation. While the group of sensor units may detect and track image focus for the overall device, it also allows the determination of color by signals received. Normally, there is one single micro-lens disposed above the entire group of sensor units (such as the group of Phase Difference Auto Focus pixels). In other words, all sensor units within the group shares one single micro-lens, while other sensor units each has one micro-lens disposed on top. The single micro-lens above the group of sensor units may enable light to converge together for tracking and detecting. For example, when light is entered at an inclined angle, one of the sensor units within the group may receive more light than another sensor unit, and thus based on the signal reading between the sensor units, entry light direction may be accurately determined.

Under ideal conditions, the single micro-lens above the group of sensor units allows incident light rays to converge at a center point of the group of sensor units from the top view to form a light spot. The group of sensor units is often arranged in an array, and each sensor unit is laterally surrounded by a deep trench isolation (DTI) structure. In other words, the deep trench isolation structure may be a grid structure that compartmentalizes the array of sensor units. When the array is arranged in 2×2, for example, the center point where the light spot converges may be located at an intersecting position of the deep trench isolation structure. Through the deep trench isolation structure, the light spot may be further scattered toward surrounding sensing portions embedded in a substrate for reception. In the event when process variation occurs, such as an unintentional misalignment of the micro-lens structure, the light spot may be shifted away from the center point of the group of sensor units. As a result, light rays scattered from the light spot may be transmitted beyond the group of sensor units into adjacent units of different color, which may result in unwanted cross talk.

It should be understood that, due to continuing reduction of sensor unit size, even if the alignment of the micro-lens structure were exact (which is still a great challenge based on present precision technology), the light rays scattered from the light spot may still be transmitted beyond the group of sensor units. This is because the traveling path of the light rays is too short (due to sensor unit size), and the light rays may not be fully absorbed by the substrate material before reaching the border of the group of sensor units. For larger sensor units, this issue may be of less concern. However, since the industry favors smaller sensor units, the cross talk of image sensors is significantly manifested.

When light rays cannot be properly and evenly received by the designated sensor units, the display performance may be compromised. For example, when one individual sensor unit is selected from each of several groups of sensor units and combined to form a first pixel, the first pixel may display a specific color from accumulating the signals read from each selected sensor units. When another individual sensor unit is selected from each of the same groups of sensor units and combined to form a second pixel, the second pixel may display a specific color from accumulating the signals read from each selected sensor units. Ideally, the first pixel and the second pixel should display the same color. However, if the sensor units within each group receive different light intensity, which may be a result of light leaking into adjacent units, the signals converted between the sensor units would be significantly different. As a result, there may be a severe color variation between the first pixel and the second pixel, which causes channel imbalance and affects the quality of the displayed image.

According to some embodiments of the present disclosure, in addition with the existing deep trench isolation structure, an innovative extra deep trench isolation structure may be disposed within each sensor unit to address the above issues. Incorporating the extra deep trench isolation structure of the present disclosure within the sensor unit may block the light rays that may potentially travel beyond the group of sensor units, in which the light rays may be forced to reflect back toward the center of the group of sensor units. Therefore, by further confining light rays within the group of sensor units as intended, cross talk may be eliminated, and the effect of channel imbalance may also reduce. Furthermore, due to the improvement on cross talk and channel imbalance, quantum efficiency may also be enhanced.

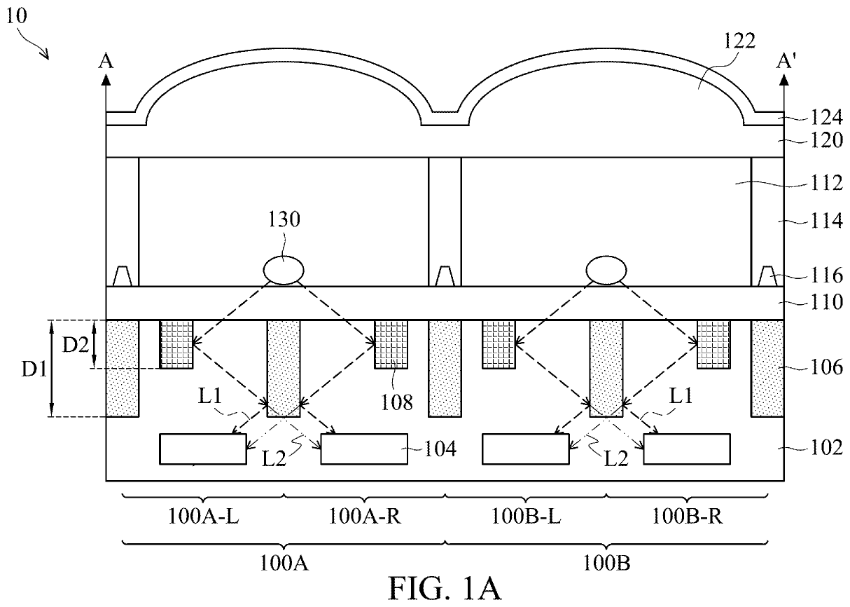

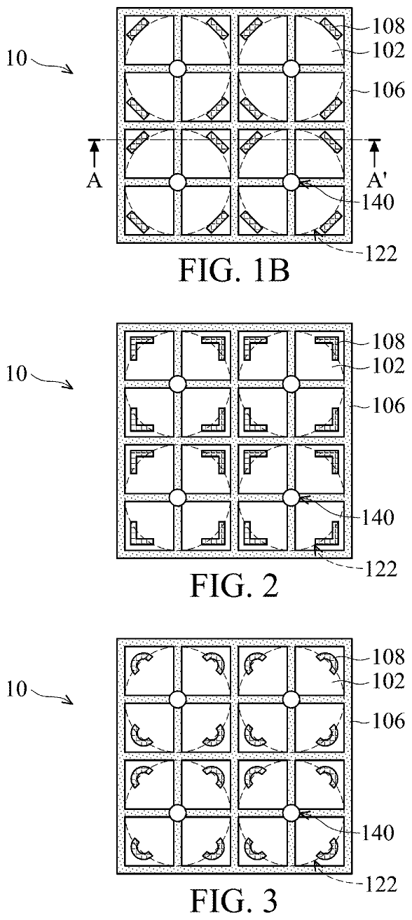

FIG. 1A is a cross-sectional view of an image sensor 10, according to some embodiments of the present disclosure. In some embodiments, image sensors may contain millions of sensor units in reality. For the sake of brevity, FIG. 1A only displays a portion of an actual image sensor. The image sensor 10 shown in FIG. 1A includes two groups of sensor units 100A and 100B disposed adjacent to each other. From a top view of one of the groups of sensor units 100A and 100B (shown in FIG. 1B), each of the groups of sensor units 100A and 100B may include four sensor units arranged in 2×2, but the present disclosure is not limited thereto. For example, the group of sensor units 100A and the group of sensor units 100B may correspond to m×n photoelectric conversion elements, in which m and n are positive integers that can be the same or different, but the present disclosure is not limited thereto. For illustration purpose, the group of sensor units 100A and the group of sensor units 100B both include one left sensor unit and one right sensor units. In particular, the group of sensor units 100A includes a left sensor unit 100A-L and a right sensor unit 100A-R, and the group of sensor units 100B includes a left sensor unit 100B-L and a right sensor unit 100B-R.

Please note that, as shown in FIG. 1A, one micro-lens 122 may be disposed on each of the group of sensor units 100A and the group of sensor units 100B, and a light spot 130 may be converged at the center of each of the group of sensor units 100A and the group of sensor units 100B. In a conventional design, a deep trench isolation structure 106 may be disposed surrounding each of the left sensor unit 100A-L, the right sensor unit 100A-R, the left sensor unit 100B-L, and the right sensor unit 100B-R. For that reason, the deep trench isolation structure 106 may also be considered as a boundary deep trench isolation structure, which defines the size of each of the left sensor unit 100A-L, the right sensor unit 100A-R, the left sensor unit 100B-L, and the right sensor unit 100B-R. For clarity purpose, the deep trench isolation structure 106 will be referred to as a first deep trench isolation structure 106 thereafter. Although the first deep trench isolation structure 106 alone may block and reflect back outbound light rays, it has gradually became inadequate as the sensor unit size shrinks. The presence of a second deep trench isolation structure 108 may increase the light reflection probability, which in turn decrease the probability of the light rays traveling beyond each of the group of sensor units 100A and the group of sensor units 100B. Furthermore, the inventor has discovered that the second deep trench isolation structure 108 should be asymmetrical with respect to a horizontal middle line or a vertical middle line within each of the left sensor unit 100A-L, the right sensor unit 100A-R, the left sensor unit 100B-L, and the right sensor unit 100B-R from the top view. The asymmetrical feature will be described in detail in reference with FIG. 1B.

Referring to FIG. 1A, each of the group of sensor units 100A and the group of sensor units 100B includes a plurality of sensing portions 104, a color filter layer 112, and a micro-lens 122. The plurality of sensing portions 104 may be embedded in a substrate 102. Moreover, the first deep trench isolation structure 106 and the second deep trench isolation structure 108 are also embedded within the substrate 102. According to some embodiments of the present disclosure, the first deep trench isolation structure 106 laterally separates each sensing portion 104, while the second deep trench isolation structure 108 are disposed above each sensing portion 104. In some embodiments, the substrate 102 may be a single structure shared by all sensor units of the image sensor 10. Furthermore, an anti-reflection layer 110 may be disposed on the substrate 102.

In some embodiments, the substrate 102 may be, for example, a wafer or a chip, but the present disclosure is not limited thereto. In some embodiments, the substrate 102 may be a semiconductor substrate, for example, silicon substrate. Furthermore, in some embodiments, the semiconductor substrate may also be an elemental semiconductor including germanium, a compound semiconductor including gallium nitride (GaN), silicon carbide (SiC), gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, gallium indium arsenide (GaInAs) alloy, gallium indium phosphide (GaInP) alloy, and/or gallium indium arsenide phosphide (GaInAsP) alloy, or a combination thereof. In some embodiments, the substrate 102 may be a photoelectric conversion substrate, such as a silicon substrate or an organic photoelectric conversion layer.

In other embodiments, the substrate 102 may also be a semiconductor on insulator (SOI) substrate. The semiconductor on insulator substrate may include a base plate, a buried oxide layer disposed on the base plate, and a semiconductor layer disposed on the buried oxide layer. Furthermore, the substrate 102 may be an N-type or a P-type conductive type.

In some embodiments, the substrate 102 may include various P-type doped regions and/or N-type doped regions (not shown) formed by, for example, an ion implantation and/or diffusion process. In some embodiments, transistors, photodiodes, or the like, may be formed at the active regions, defined by the first deep trench isolation structure 106.

As mentioned above, the substrate 102 may include the first deep trench isolation structure 106 and the second deep trench isolation structure 108 (which may be collectively known as an isolation structure). In some embodiments, the first deep trench isolation structure 106 may define active regions, and electrically isolate active region elements within or above the substrate 102, but the present disclosure is not limited thereto. As stated earlier, the first deep trench isolation structure 106 may help scattering light spots 130. In some embodiments, the first deep trench isolation structure 106 and the second deep trench isolation structure 108 may both reflect and refract incident light rays being focused thereon. In other embodiments, additional isolation structures may be applied as an alternative. Shallow trench isolation (STI) structures and local oxidation of silicon (LOCOS) structures are examples of other isolation structures.

Referring to FIG. 1A, the first deep trench isolation structure 106 surrounds the left sensor unit 100A-L, the right sensor unit 100A-R, the left sensor unit 100B-L, and the right sensor unit 100B-R from the top view, while the second deep trench isolation structure 108 may be enclosed by the first deep trench isolation structure 106. According to some embodiments of the present disclosure, the second deep trench isolation structure 108 may be located close to a corner of the left sensor unit 100A-L, the right sensor unit 100A-R, the left sensor unit 100B-L, and the right sensor unit 100B-R defined by the first deep trench isolation structure 106. The first deep trench isolation structure 106 has a first depth D1 extending into the substrate 102, and the second deep trench isolation structure 108 has a second depth D2 extending into the substrate 102. In some embodiments, the first depth D1 is larger than the second depth D2. In a specific embodiment of the present disclosure, the second depth D2 may be approximately less than 1 μm.

As mentioned previously, incorporating the second deep trench isolation structure 108 of the present disclosure may enhance the quantum efficiency and may eliminate the cross talk and the channel imbalance. In some embodiments, the quantum efficiency is the photoelectrical transferring efficiency, which is the measure of how efficient incident lights can be converted into electrical signal. The cross talk is the reading of signal of different light color interfering with the desired light color. The channel imbalance is the ratio of strongest light intensity received and the weakest light intensity received, which is the measure of light reception uniformity within the group of sensor units. In other words, lower quantum efficiency and higher cross talk and channel imbalance are unwanted characteristics, as they may affect the performance of image sensors. The second deep trench isolation structure 108 may effectively address the above issues, leading to higher quantum efficiency and less cross talk and channel imbalance.

In the embodiment where the substrate is made of silicon, light rays travelling within the medium of silicon material may possess the characteristics of relatively long wavelength and relatively weak absorption within the medium. In that way, scattered light rays are more likely to be transmitted into neighboring sensor units (especially sensor units with smaller size) of different color, resulting in severe cross talk. If the second deep trench isolation structure 108 were designed to have symmetrical feature with respect to the horizontal middle line or the vertical middle line within the left sensor unit 100A-L, the right sensor unit 100A-R, the left sensor unit 100B-L, and the right sensor unit 100B-R, only half the optical energy may be confined, while the other half may be lost, which still causes notable cross talk effect. According to some embodiments of the present disclosure, the asymmetrical feature of the second deep trench isolation structure 108 requires both the first deep trench isolation structure 106 and the second deep trench isolation structure 108 to create a partially confined space, which may be oriented around the center of each of the group of sensor units 100A and the group of sensor units 100B. It should be noted that the partially confined space may also correspond to where each of the light spot 130 is.

Still referring to FIG. 1A, the arrangement of the first deep trench isolation structure 106 and the second deep trench isolation structure 108 allows light rays L1 and light rays L2 to be channeled into the partially confined space. The confinement characteristics oriented around the center of the group of sensor units 100A and the group of sensor units 100B increases propagation paths of the light rays L1 and the light rays L2, allowing the light rays L1 and the light rays L2 to be more efficiently received by the plurality of sensing portions 104, thereby improving the quantum efficiency and the cross talk. More specifically, even if the light rays, such as the light rays L2, were transmitted into neighboring sensor units, the transmission may still take place within the same color units. As shown in FIG. 1A, the light rays L2 may travel from the left sensor unit 100A-L to the right sensor unit 100A-R, from the right sensor unit 100A-R to the left sensor unit 100A-L, from the left sensor unit 100B-L to the right sensor unit 100B-R, or from the right sensor unit 100B-R to the left sensor unit 100B-L. Furthermore, the light rays L2 may compensate uneven light reception between the left sensor unit 100A-L and the right sensor unit 100A-R or between the left sensor unit 100B-L and the right sensor unit 100B-R, resulting in improved channel imbalance.

From the perspective of the light rays L1 and the light rays L2, the light travelling inside the substrate 102 may be trapped by (or sandwiched between) the first deep trench isolation structure 106 and the second deep trench isolation structure 108. Since the first deep trench isolation structure 106 and the second deep trench isolation structure 108 both have lower refraction index than that of the material of the substrate 102, the light may be reflected at the interface between the material of high refractive index and the material of low refractive index (for example, the interface between the first deep trench isolation structure 106 and the substrate 102, or the interface between the second deep trench isolation structure 108 and the substrate 102). The addition of the second deep trench isolation structure 108 may further confine the optical propagation. As a result, the medium of propagation may have higher effective index, in order to enhance waveguide effect for higher optical reception by the plurality of sensing portions 104.

In the medium of higher effective index (due to the presence of the second deep trench isolation structure 108), the optical propagation may only be reflected rather than scattered. By designing the second depth D2 of the second deep trench isolation structure 108 to be smaller than the first depth D1 of the first deep trench isolation structure 106, the light traveling inside the substrate 102 may also propagate through a medium of lower effective index (without the presence of the second deep trench isolation structure 108) before reaching the plurality of sensing portions 104. In the medium of lower effective index, the optical propagation may also be scattered. According to some embodiments of the present disclosure, the light rays L1 may be reflected toward the respective sensing portions 104, while the light rays L2 may be scattered toward adjacent sensing portions 104 within the same group of sensor units.

For example, the light rays L2 may propagate from the left sensor unit 100A-L to the right sensor unit 100A-R, from the right sensor unit 100A-R to the left sensor unit 100A-L, from the left sensor unit 100B-L to the right sensor unit 100B-R, or from the right sensor unit 100B-R to the left sensor unit 100B-L. Since the light rays traveling within the group of sensor units 100A or within the group of sensor units 100B are of the same color, optical propagation between the left sensor unit 100A-L and the right sensor unit 100A-R, or between the left sensor unit 100B-L and the right sensor unit 100B-R may not suffer significant cross talk. By allowing the plurality of sensing portions 104 to receive the light with longer optical path including both reflected light rays (the light rays L1) and scattered light rays (the light rays L2), the quantum efficiency may be further enhanced.

In some embodiments, the formation of the first deep trench isolation structure 106 and the second deep trench isolation structure 108 may include, for example, forming an insulating layer on the substrate 102. Through a photolithography patterning and etching, trenches may be formed extending into the substrate 102. The photolithography process may include resist coating, soft baking, exposure, post-exposure baking, development, the like, or combinations thereof. The etching process may include dry etching, wet etching, the like, or combinations thereof. By controlling the etching parameters, trenches of different depths may be produced that correspond to the subsequently formed first deep trench isolation structure 106 and second deep trench isolation structure 108.

Next, a liner of rich nitrogen-containing materials (such as silicon oxynitride) may be grown conformally along the trenches. After that, insulating materials (such as silicon dioxide, silicon nitride, or silicon oxynitride) may be filled into the trenches by any suitable deposition processes, such as chemical vapor deposition (CVD), high-density plasma chemical vapor deposition (HDP-CVD), plasma-enhanced chemical vapor deposition, flowable chemical vapor deposition (FCVD), sub-atmospheric chemical vapor deposition (SACVD), the like, or combinations thereof. An annealing process may then be performed on the insulating materials in the trenches, followed by a planarization process, such as chemical mechanical polish (CMP), on the substrate 102 to remove excessive insulating materials, so the insulating materials in the trenches are level with the top surface of the substrate 102.

According to some embodiments of the present disclosure, the refractive index of the second deep trench isolation structure 108 is approximately between 1.3 and 2.5. The refractive index of the first deep trench isolation structure 106 may be larger than, equal to, or smaller than the refractive index of the second deep trench isolation structure 108. The refractive index is a characteristic of a substance that changes the speed of light, and is a value obtained by dividing the speed of light in vacuum by the speed of light in the substance. When light travels between two different materials at an angle, its refractive index determines the angle of light transmission (refraction).

Referring to FIG. 1A, the anti-reflection layer 110 is disposed on the substrate 102. In some embodiments, the anti-reflection layer 110 is configured to decrease the reflection of the light being transmitted to the plurality of sensing portions 104. In some embodiments, the anti-reflection layer 110 is disposed horizontally in correspondence (or parallel with respect) to the array of sensing portions 104. In some embodiments, the materials of the anti-reflection layer 110 may include SiOₓN_{y} (wherein x and y are in the range of 0 to 1). The anti-reflection layer 110 may be formed by any suitable deposition processes.

As mentioned above, the group of sensor units 100A and the group of sensor units 100B may each include a color filter layer 112 disposed on the anti-reflection layer 110. In some embodiments, the height of the color filter layer 112 may be approximately between 0.3 μm and 2.0 μm. In a particular embodiment, the height of the color filter layer 112 may be approximately 0.9 μm. In some embodiments, the color filter layer 112 may include multiple units, which may be colored red, green, blue, white, or infrared. Each unit of the color filter layer 112 may corresponds to one respective sensing portion 104 of the image sensor 10, and the color of the unit depends on the requirement of each of the group of sensor units 100A and the group of sensor units 100B. The substrate 102 may absorb the filtered light rays and generate free electrons that are then travel toward the respective sensing portion 104. The respective sensing portions 104, such as photodiodes, may convert received light signals into electric signals for each of the group of sensor units 100A and the group of sensor units 100B. In some embodiments, sensor units within the same group may have the same color units. In some embodiments, the group of sensor units 100A and the group of sensor units 100B are separated from each other by the partition grid structure 114, which will be explained in detail later. According to some embodiments of the present disclosure, the color filter layer 112 is deposited on the anti-reflection layer 110 and in the space defined by the partition grid structure 114. The color filter layer 112 may be formed in sequence by a coating, exposure, and development process at different steps. Alternatively, the color filter layer 112 may be formed by ink-jet printing.

Referring to FIG. 1A, the partition grid structure 114 is disposed between one or more units of the color filter layer 112. For example, the center line (not shown) of the partition grid structure 114 may define the border of the group of sensor units 100A and the group of sensor units 100B. According to some embodiments of the present disclosure, the partition grid structure 114 may have a lower refractive index than each unit of the color filter layer 112. According to some embodiments of the present disclosure, the refractive index of the partition grid structure 114 is approximately between 1.00 and 1.99. When incident light enters the color filter layer 112, the partition grid structure 114 may isolate light rays within the specific unit to serve as the light-trapping function.

Materials of the partition grid structure 114 may include a transparent dielectric material. At first, a partition material layer is coated on the anti-reflection layer 110. Next, a hard mask layer (not shown) is coated on the partition material layer. In some embodiments, the material of the hard mask layer may be a photoresist. A photolithography process is performed on the hard mask layer for patterning. Next, an etching process is performed on the partition material layer by using the patterned hard mask layer. The etching process may be dry etching. After the etching process, a portion of the partition material layer is removed on the anti-reflection layer 110, and multiple openings are formed therein. As mentioned previously, the openings will be subsequently filled with the color filter layer 112.

Still referring to FIG. 1A, a light shielding structure 116 is disposed on the anti-reflection layer 110 between the group of sensor units 100A and the group of sensor units 100B. In some embodiments, the light shielding structure 116 is embedded within the partition grid structure 114. In some embodiments, the partition grid structure 114 may be higher than or equal to the light shielding structure 116, depending on the design requirements for the image sensors 10. In some embodiments, the light shielding structure 116 spans across the border of the group of sensor units 100A and the group of sensor units 100B. In other words, the light shielding structure 116 is disposed in a way shared by any two adjacent sensor units (for example, the right sensor unit 100A-R and the left sensor unit 100B-L). The arrangement of the light shielding structure 116 may prevent one of the sensing portions 104 under the corresponding unit of the color filter layer 112 to receive additional light from an adjacent unit of different color, which may affect the accuracy of signals received. In some embodiments of the present disclosure, the height of the light shielding structure 116 may be approximately between 0.005 μm and 2.000 μm. In some embodiments, materials of the light shielding structure 116 may include opaque metals (such as tungsten (W), aluminum (Al)), opaque metal nitride (such as titanium nitride (TiN)), opaque metal oxide (such as titanium oxide (TiO)), other suitable materials, or combinations thereof, but the present disclosure is not limited thereto. The light shielding structure 116 may be formed by depositing a metal layer on the anti-reflection layer 110 and then patterning the metal layer using photolithography and etching processes to form the light shielding structure 116, but the present disclosure is not limited thereto.

Referring to FIG. 1A, the micro-lens material layer 120 is disposed on the color filter layer 112 and the partition grid structure 114. In some embodiments, materials of the micro-lens material layer 120 may be a transparent material. For example, the materials may include glass, epoxy resin, silicone resin, polyurethane, any other applicable material, or combinations thereof, but the present disclosure is not limited thereto. According to some embodiments of the present disclosure, a plurality of micro-lenses 122 are disposed on the micro-lens material layer 120. In some embodiments, the plurality of micro-lenses 122 may be formed by patterning a top portion of the micro-lens material layer 120 to correspond to each of the group of sensor units 100A and the group of sensor units 100B. Because the plurality of micro-lenses 122 are formed from the micro-lens material layer 120, the plurality of micro-lenses 122 and the micro-lens material layer 120 share the same material.

Still referring to FIG. 1A, a top film 124 may be conformally deposited onto the surface of the plurality of micro-lenses 122. In some embodiments, the top film 124 is a continuous structure that covers the entire surface of the image sensor 10. According to some embodiments of the present disclosure, the material of the top film 124 has a lower refractive index than that of the micro-lenses 122 (or the micro-lens material layer 120). The refractive index of the material of the top film 124 is higher than that of air. In some embodiments, there is a large difference between the refractive index of air and the refractive index of the micro-lenses 122. The large difference between refractive indices may cause some incident light rays to reflect away from the surface of the micro-lenses 122, instead of refract into the color filter layer 112. This will cause the image sensor 10 to lose optical energy, decreasing the amount of light intensity that the plurality of sensing portions 104 would have received. The addition of the top film 124 may serve as a buffer for the large refractive difference between ambient air and the micro-lenses 122, so the optical energy loss may be minimized. In some embodiments, the top film 124 may be a transparent material including, for example, a glass, epoxy resin, silicone resin, polyurethane, other suitable materials, or a combination thereof, but the present disclosure is not limited thereto. The formation of the top film 124 may include deposition processes, which may include, for example, spin-on coating process, chemical vapor deposition (CVD), physical vapor deposition (PVD), atomic layer deposition (ALD), other suitable methods, or a combination thereof.

In a specific embodiment, the image sensor 10 having the second deep trench isolation structures 108 within the left sensor unit 100A-L, the right sensor unit 100A-R, the left sensor unit 100B-L, and the right sensor unit 100B-R is being compared with a conventional image sensor having only the first deep trench isolation structure 106. In summary, the quantum efficiency of the image sensor 10 is 6% higher than that of the conventional image sensor, the cross talk of the image sensor 10 is 14% lower than that of the conventional image sensor, and the channel imbalance of the image sensor 10 is also 14% lower than that of the conventional image sensor. Therefore, the design of the present disclosure can enhance the image sensor performance.

FIG. 1B is a top view of the image sensor 10, according to some embodiments of the present disclosure. It should be noted that FIG. 1A is the cross-sectional view obtained from a line A-A′ of FIG. 1B. As mentioned, each of the group of sensor units 100A or the group of sensor units 100B may include four sensor units arranged in 2×2. In FIG. 1B, four groups of sensor units are provided, which are also arranged in 2×2. In other words, there are a total of sixteen sensor units arranged in 4×4. For illustrative purpose, the anti-reflection layer 110, the color filter layer 112, the partition grid structure 114, the light shielding structure 116, and the top film 124 are omitted. In some embodiments, the substrate 102 is compartmentalized by the grid form of the first deep trench isolation structure 106 into the sixteen sensor units. The second deep trench isolation structures 108 are enclosed by the first deep trench isolation structure 106. Furthermore, the locations of the micro-lenses 122 are also indicated in dashed lines. As mentioned previously, each micro-lens 122 corresponds to one respective group of sensor units.

Referring to FIG. 1B, each group of sensor units of image sensor 10 may be of the same color. A center point 140 is indicated for reference. In some embodiments, the center point 140 is located at the center of the group of “same-colored” units. According to some embodiments of the present disclosure, the second deep trench isolation structures 108 within each group of sensor units are symmetrical with respect to the center point 140. In a specific embodiment of the present disclosure, the second deep trench isolation structures 108 are rectangular shapes having a width less than 180 nm and a length less than the length of any of the sensor units. The shapes of the second deep trench isolation structures 108 are not limited thereto. According to some embodiments of the present disclosure, the area of the second deep trench isolation structures 108 from the top view is less than 35% of the area of any of the sensor units, as long as the scattering light rays that may travel beyond the group of sensor units may be properly blocked.

FIGS. 2, 3, 4, 5, 6, and 7 are top views of the image sensor 10 with various designs, according to some embodiments of the present disclosure. As mentioned previously, the second deep trench isolation structure 108 may be located close to a corner within the sensor unit from the top view. In the following examples, the second deep trench isolation structure 108 may also extend from the corner toward at least one of the adjacent corners or a diagonal corner of the sensor unit. The shapes of the second deep trench isolation structure 108 may vary, as long as the area of which is maintained under 35% of the area of any of the sensor units. For illustrative purpose, the anti-reflection layer 110, the color filter layer 112, the partition grid structure 114, the light shielding structure 116, and the top film 124 are omitted. The features of the substrate 102, the first deep trench isolation structure 106, the second deep trench isolation structures 108, and the micro-lenses 122 are similar to those illustrated in FIG. 1B, and the details are not described again herein to avoid repetition.

Referring to FIG. 2, the second deep trench isolation structures 108 are L-shapes. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

Referring to FIG. 3, the second deep trench isolation structures 108 are arc shapes. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

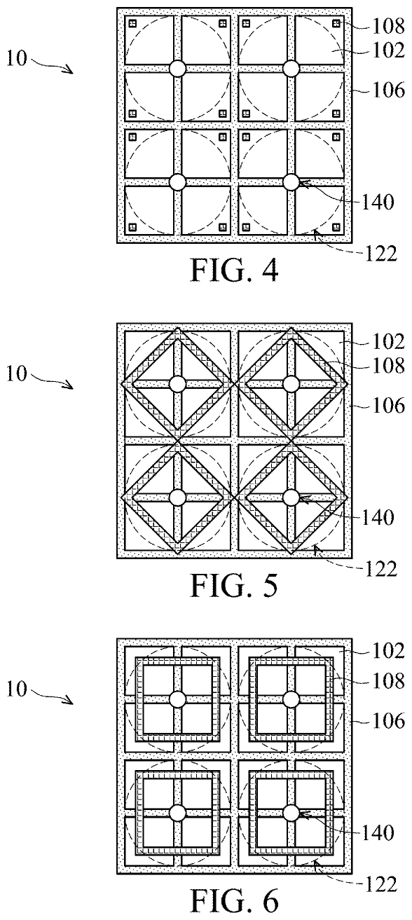

Referring to FIG. 4, the second deep trench isolation structures 108 are square shapes. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

Referring to FIG. 5, the second deep trench isolation structure 108 is a continuous ring structure of diamond shape across each of the entire groups of sensor units from the top view. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

Referring to FIG. 6, the second deep trench isolation structure 108 is a continuous ring structure of square shape across each of the entire groups of sensor units from the top view. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

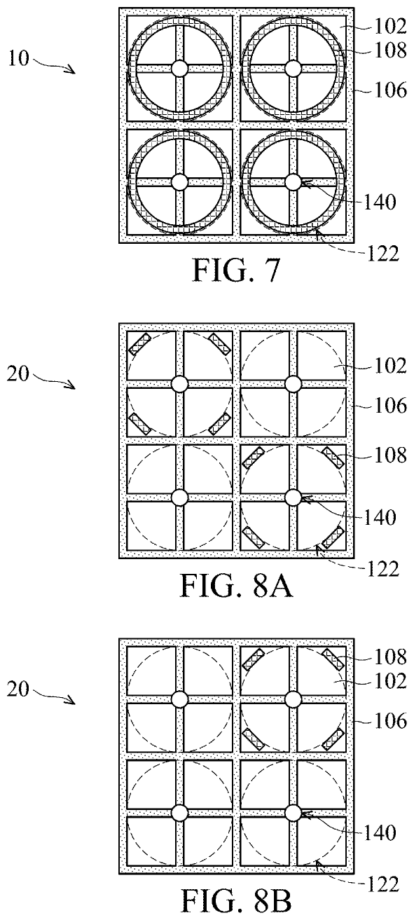

Referring to FIG. 7, the second deep trench isolation structure 108 is a continuous ring structure of circular shape across each of the entire groups of sensor units from the top view. The micro-lenses 122 correspond to the groups of sensor units, respectively. According to some embodiments, each group of sensor units of the image sensor 10 may be of the same color. The center point 140 is located at the center of the group of “same-colored” units. According to some embodiments of the present disclosure, the second deep trench isolation structures 108 within each group of sensor units are symmetrical with respect to the center point 140. However, the second deep trench isolation structure 108 is asymmetrical with respect to a horizontal middle line or a vertical middle line within each sensor unit.

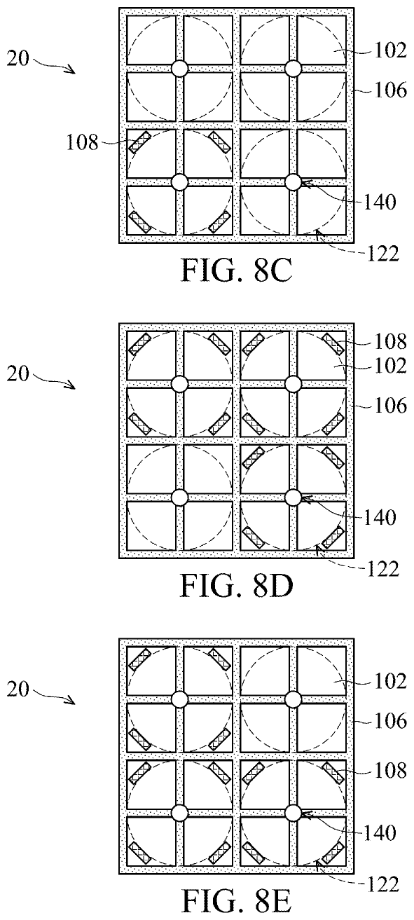

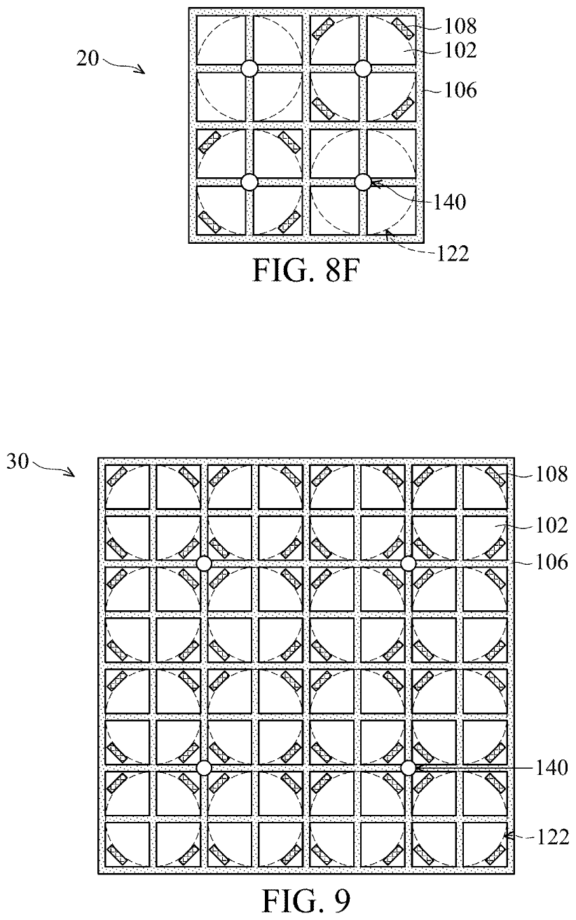

FIGS. 8A-8F are top views of an image sensor 20 with various designs, according to other embodiments of the present disclosure. In comparison with the image sensor 10 shown in FIG. 1B, the second deep trench isolation structures 108 may not be present in every group of sensor units. For illustrative purpose, the anti-reflection layer 110, the color filter layer 112, the partition grid structure 114, the light shielding structure 116, and the top film 124 are omitted. The features of the substrate 102, the first deep trench isolation structure 106, the second deep trench isolation structures 108, and the micro-lenses 122 are similar to those illustrated in FIG. 1B, and the details are not described again herein to avoid repetition.

Referring to FIG. 8A, among the four groups of sensor units arranged in 2×2, the second deep trench isolation structures 108 are only present in two of the four groups of sensor units. For example, the second deep trench isolation structure 108 may only need to be disposed in the green-colored groups of sensor units, whenever the green-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

Referring to FIG. 8B, among the four groups of sensor units arranged in 2×2, the second deep trench isolation structures 108 are only present in one of the four groups of sensor units. For example, the second deep trench isolation structure 108 may only need to be disposed in the red-colored groups of sensor units, whenever the red-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

Referring to FIG. 8C, among the four groups of sensor units arranged in 2×2, the second deep trench isolation structures 108 are only present in one of the four groups of sensor units. For example, the second deep trench isolation structure 108 may only need to be disposed in the blue-colored groups of sensor units, whenever the blue-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

Referring to FIG. 8D, among the four groups of sensor units arranged in 2×2, the second deep trench isolation structures 108 are present in three of the four groups of sensor units. For example, the second deep trench isolation structure 108 may need to be disposed in the green-colored and the red-colored groups of sensor units, whenever the green-colored and the red-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

Referring to FIG. 8E, among the four groups of sensor units arranged in 2×2, the second deep trench isolation structures 108 are present in three of the four groups of sensor units. For example, the second deep trench isolation structure 108 may need to be disposed in the green-colored and the blue-colored groups of sensor units, whenever the green-colored and the blue-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

Referring to FIG. 8F, among the four groups of sensor units arranged in 2×2, the second deep trench isolation structures 108 are only present in two of the four groups of sensor units. For example, the second deep trench isolation structure 108 may only need to be disposed in the red-colored and the blue-colored groups of sensor units, whenever the red-colored and the blue-colored groups of sensor units tend to impose significantly more cross talk toward neighboring groups of sensor units than the other colored groups of sensor units. The center point 140 is located at the center of the group of “same-colored” units. According to some embodiments of the present disclosure, the second deep trench isolation structures 108 within each group of sensor units (if present) are symmetrical with respect to the center point 140. However, the second deep trench isolation structure 108 is asymmetrical with respect to a horizontal middle line or a vertical middle line within each sensor unit.

FIGS. 9, 10, 11, 12, 13, 14, 15, and 16 are top views of an image sensor 30 with various designs, according to yet other embodiments of the present disclosure. In comparison with the image sensor 10 shown in FIG. 1B, while each of the group of sensor units may also include four sensor units arranged in 2×2, sixteen groups of sensor units are provided and arranged in 4×4. In other words, there are a total of sixty-four sensor units arranged in 8×8. Among the 4×4 array of the sixteen groups of sensor units, every four groups of sensor units with the same color are arranged together in a 2×2 array. Different from the image sensor 10, in which each center point 140 is located at the center of each group of sensor units, each center point 140 of the image sensor 30 is located at the center of every four groups of sensor units arranged in the 2×2 array.

It should be noted that, each center point 140 of the image sensor 10 and the image sensor 20 is located within each group of sensor units (such as under each micro-lens 122). However, when more groups of sensor units are arranged, each center point 140 may be located outside each group of sensor units (such as not under any micro-lens 122). It should be appreciated that, the locations of the center points 140 depend on the arrangement and quantity of the groups of sensor units, and are not associated with the configuration of the micro-lenses 122. For illustrative purpose, the anti-reflection layer 110, the color filter layer 112, the partition grid structure 114, the light shielding structure 116, and the top film 124 are omitted. The features of the substrate 102, the first deep trench isolation structure 106, the second deep trench isolation structures 108, and the micro-lenses 122 are similar to those illustrated in FIG. 1B, and the details are not described again herein to avoid repetition.

Referring to FIG. 9, the image sensor 30 is designed on the basis of the image sensor 10 described in FIG. 1B. The image sensor 30 may be considered as an expansion of the image sensor 10 shown in FIG. 1B, from four groups of sensor units in the 2×2 array to sixteen groups of sensor units in the 4×4 array. Each center point 140 is located at the center of every four groups of sensor units having the same color that are arranged in the 2×2 array. Image sensor 30 maintains the same principle outlined throughout the present disclosure, where the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

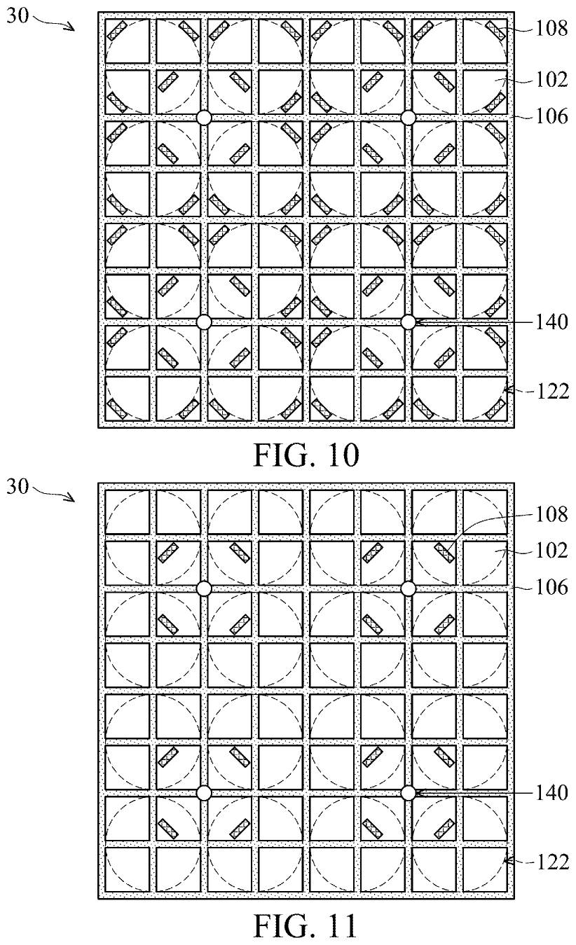

Referring to FIG. 10, the image sensor 30 is designed on the basis of the image sensor 30 described in FIG. 9. In comparison with the image sensor 30 of FIG. 9, the second deep trench isolation structures 108 closest to the center points 140 are shifted outward to the corners within the sensor units furthest away from the center points 140. It should be noted that, all of the second deep trench isolation structures 108 are disposed near the corners of the sensor units equally apart from the center points 140. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

Referring to FIG. 11, the image sensor 30 is designed on the basis of the image sensor 30 described in FIG. 10. In comparison with the image sensor 30 of FIG. 10, the second deep trench isolation structures 108 within all of the sensor units not directly adjacent to the center points 140 are removed. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

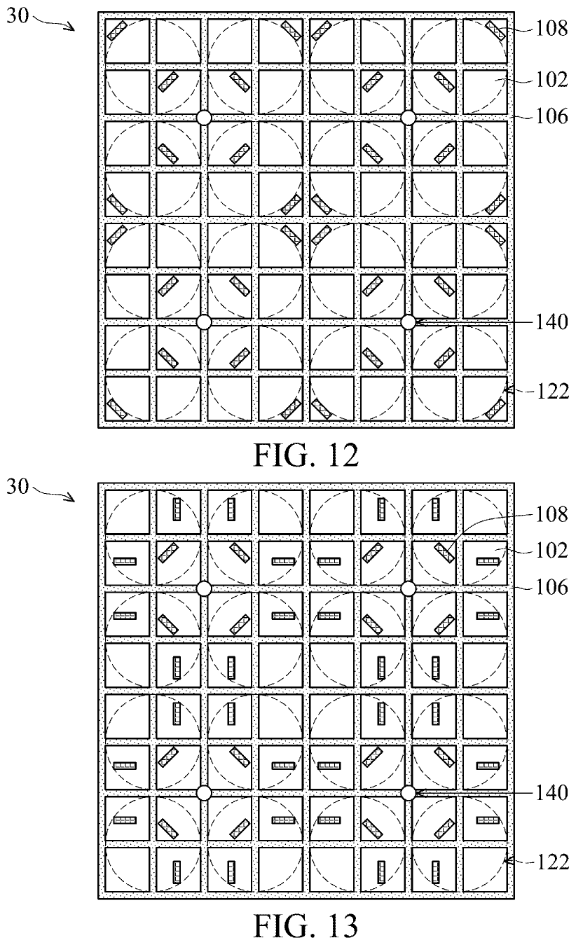

Referring to FIG. 12, the image sensor 30 is also designed on the basis of the image sensor 30 described in FIG. 10. In comparison with the image sensor 30 of FIG. 10, the second deep trench isolation structures 108 within some of the sensor units not directly adjacent to the center points 140 are removed. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

Referring to FIG. 13, the image sensor 30 is designed on the basis of the image sensor 30 described in FIG. 11. In comparison with the image sensor 30 of FIG. 11, the second deep trench isolation structures 108 are added into some of the sensor units not directly adjacent to the center points 140. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

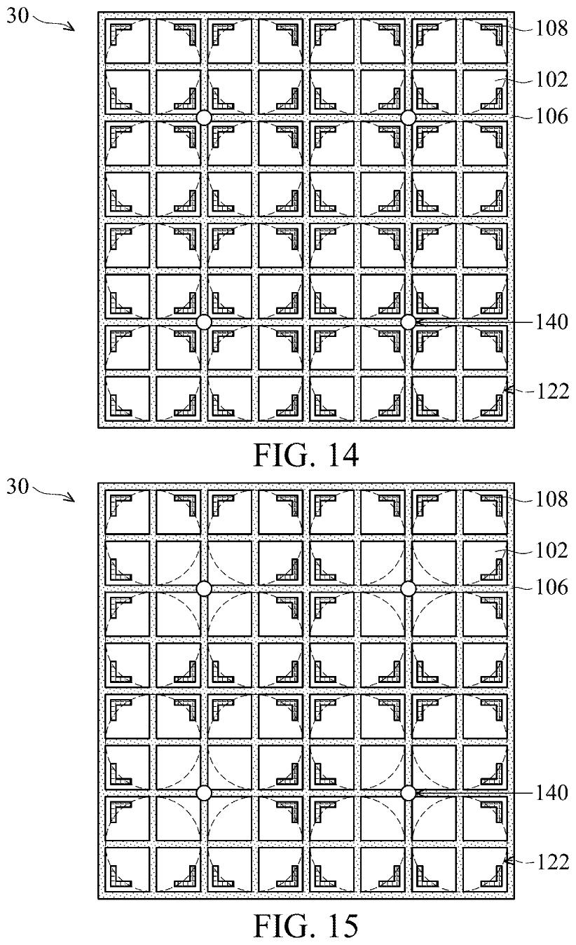

Referring to FIG. 14, the image sensor 30 is designed on the basis of the image sensor 10 described in FIG. 2. The image sensor 30 may be considered as an expansion of the image sensor 10 shown in FIG. 2, from four groups of sensor units in the 2×2 array to sixteen groups of sensor units in the 4×4 array. Each center point 140 is located at the center of every four groups of sensor units having the same color that are arranged in the 2×2 array. Image sensor 30 maintains the same principle outlined throughout the present disclosure, where the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

Referring to FIG. 15, the image sensor 30 is designed on the basis of the image sensor 30 described in FIG. 14. In comparison with the image sensor 30 of FIG. 14, the second deep trench isolation structures 108 closest to the center points 140 are removed. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

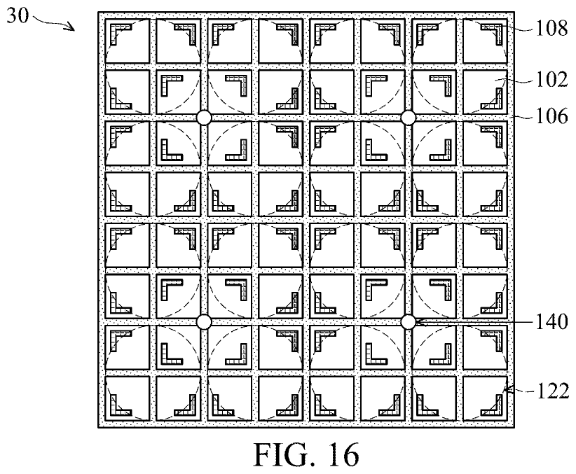

Referring to FIG. 16, the image sensor 30 is designed on the basis of the image sensor 30 described in FIG. 14. In comparison with the image sensor 30 of FIG. 14, the second deep trench isolation structures 108 closest to the center points 140 are shifted outward to the corners within the sensor units furthest away from the center points 140. After the modification, the second deep trench isolation structures 108 within all four groups of sensor units are still symmetrical with respect to the center point 140. However, the second deep trench isolation structure 108 is asymmetrical with respect to a horizontal middle line or a vertical middle line within each sensor unit.

In addition to the existing deep trench isolation structure (which constitutes a boundary for and define the area of each sensor unit), an innovative extra deep trench isolation structure may be disposed within each sensor unit to block the light rays that may potentially travel beyond the group of sensor units. The light rays being blocked by the extra deep trench isolation structure are forced to reflect back toward the center of the group of sensor units. Therefore, by further confining light rays within the group of sensor units as intended, the cross talk may be eliminated, and the channel imbalance effect may also reduce. Furthermore, due to the improvement on the cross talk and the channel imbalance, the quantum efficiency may also be enhanced.

The foregoing outlines features of several embodiments so that those skilled in the art will better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the prior art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An image sensor, comprising:
a sensor unit;
a sensing portion disposed within the sensor unit; and
an isolation structure corresponding to the sensing portion, comprising:
a first deep trench isolation (DTI) structure surrounding the sensor unit from top view; and
a second deep trench isolation structure laterally enclosed by the first deep trench isolation structure, wherein the second deep trench isolation structure is located close to a corner of the sensor unit defined by the first deep trench isolation structure, the second deep trench isolation structure is asymmetrical with respect to a horizontal middle line or a vertical middle line within the sensor unit.

2. The image sensor of claim 1, wherein the first deep trench isolation structure defines an area of the sensor unit.

3. The image sensor of claim 2, wherein an area of the second deep trench isolation structure from top view is less than 35% of the area of the sensor unit, and a critical dimension of a width of second deep trench isolation structure from top view is less than 180 nm.

4. The image sensor of claim 1, wherein two or more of the sensor units constitute a group of sensor units.

5. The image sensor of claim 4, wherein the group of sensor units has a center point from top view, and two or more of the second deep trench isolation structures of the group of sensor units are symmetrical with respect to the center point.

6. The image sensor of claim 4, further comprising a micro-lens disposed correspondingly on the group of sensor units.

7. The image sensor of claim 6, further comprising a top film disposed conformally on the micro-lens.

8. The image sensor of claim 7, wherein a refractive index of the top film is lower than a refractive index of the micro-lens.

9. The image sensor of claim 8, wherein the refractive index of the top film is higher than a refractive index of air.

10. The image sensor of claim 4, wherein the group of sensor units further comprises a color filter layer disposed on two or more of the sensing portions.

11. The image sensor of claim 10, further comprising a partition grid structure laterally surrounding the color filter layer of the group of sensor units.

12. The image sensor of claim 11, further comprising a light shielding structure embedded within the partition grid structure.

13. The image sensor of claim 4, wherein the second deep trench isolation structure is a continuous ring shape across the group of sensor units from top view.

14. The image sensor of claim 13, wherein the continuous ring shape is circular, square, or diamond.

15. The image sensor of claim 1, wherein the second deep trench isolation structure is a rectangular shape, a square shape, an arc shape, or an L-shape from top view.

16. The image sensor of claim 1, wherein the second deep trench isolation structure extends from the corner toward at least one of adjacent corners or a diagonal corner of the sensor unit.

17. The image sensor of claim 1, wherein the sensing portion and the isolation structure are embedded within a substrate.

18. The image sensor of claim 17, wherein the first deep trench isolation structure has a first depth extending into the substrate, and the second deep trench isolation structure has a second depth extending into the substrate, wherein the first depth is larger than the second depth.

19. The image sensor of claim 18, wherein the second depth is less than 1 μm.

20. The image sensor of claim 1, wherein a refractive index of the second deep trench isolation structure is between 1.3 and 2.5.
